(19) United States
(12) Patent Application Publication
(10) Pub. No.: US 2002/0136968 A1
(43) Pub. Date: Sep. 26, 2002

(54) Colored photosensitive composition

(76) Inventor: Kazuo Takebe, Osaka (JP)

Correspondence Address: BIRCH STEWART KOLASCH & BIRCH, PO BOX 747, FALLS CHURCH, VA, 22040-0747, US

(21) Appl. No.: 10/051,087

(22) Filed: Jan. 22, 2002

(30) Foreign Application Priority Data
Jan. 24, 2001 (JP) 2001-016108

(51) Int. Cl. G03F 9/00; G03C 1/73; C08J 3/28

(52) U.S. Cl. 430/7; 522/75; 522/81; 522/113; 522/134; 430/280.1

(57) ABSTRACT

This invention provides a colored photosensitive composition comprising a colorant (A), a binder polymer (B) containing monomer unit having oxetane structure, a photo-polymerizable compound (C) and a photo-polymerization initiator (D), and, using the colored photosensitive composition of the invention, color pattern having excellent solvent resistance can be formed even when the colored photosensitive composition contains the colorant (A) in a high concentration.

### BACKGROUND OF THE INVENTION

The present invention relates to a colored photosensitive composition.

Colored photosensitive composition (color resist) is implies a photosensitive composition containing colorant as an ingredient and is used for forming a color pattern (5) constituting a color filter (6). The color filter is, for instance, incorporated into a liquid crystal display device for coloring an image on a display or mounted on a solid state camera, such as a camera loading Charge Coupling Device (CCD), in order to obtains an image. The color pattern is, for instance, a color pixel (5R, 5G, 5R) or a black matrix (5BM). The color pixel consists of a colored transparent layer. Black matrix functions as a shield from light beams. These color pixels and black matrixes are formed on a substrate (2) and constitute color filters (6) respectively as shown in FIG. 1. The color pixels (5R, 5G, 5R) are transparent and transmitted light beams are colored corresponding to colors of pixels respectively, while black matrix (5BM) shields light beams.

As an example of colored photosensitive composition, those comprising (A) a colorant, (B) a binder polymer, (C) a photo-polymerizable compound and (D) photo-polymerization initiator are known. As the binder polymer (B), an alkaline-soluble resin is generally used. The color pattern (5) formed by the colored photosensitive composition preferably has a small thickness. In order to obtain a sufficiently colored pattern with thin film thickness, a colored photosensitive composition containing colorant (A) in high concentration is used.

However, there is a problem that, when a high fraction of colorant (A) is formutated in a colored photosensitive composition containing a conventional type of binder polymer (B), then resulting colored pattern tends to lack solvent resistance.

### SUMMARY OF THE INVENTION

After intensive study to obtain a colored photosensitive composition with high concentration of colorant (A) the inventors of the present invention have found that a colored pattern with an excellent solvent resistance can be obtained by using a polymer containing a monomer unit having oxetane structure as the binder polymer (B).

The present invention provides a colored photosensitive composition comprising a colorant (A), a binder polymer (B) containing monomer unit having oxetane structure, a photo-polymerizable compound (C) and a photo-polymerization initiator (D).

### BRIEF DESCRIPTION OF DRAWINGS

FIG. 1 is a schematic diagram showing a structure of a color filter.

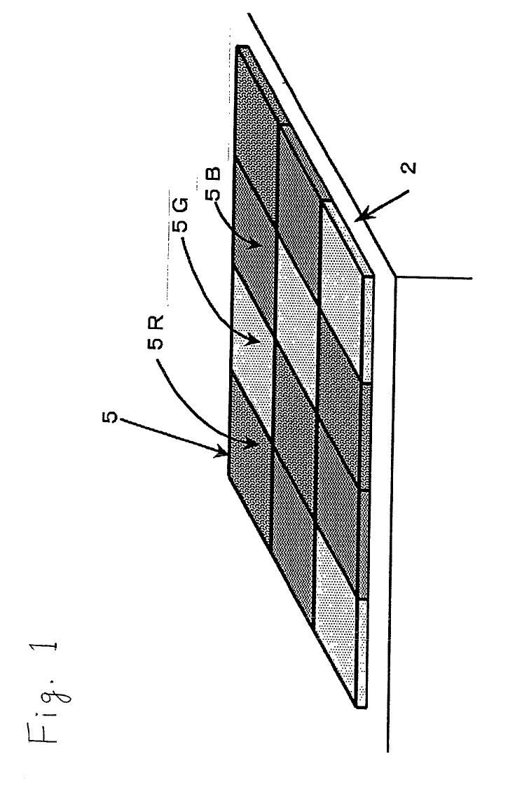

FIG. 2 is a schematic diagram showing steps for forming color pattern using a colored photosensitive composition.

In the drawings,

1 denotes a colored photosensitive composition layer,

11 denotes a non-irradiated area,

12 denotes a irradiated area,

2 denotes a substrate,

3 denotes a photo-mask,

31 denotes a glass plate,

32 denotes a light-insulating layer,

33 denotes a translucent area,

4 denotes a light beam,

5 denotes a color pattern (a color pixel or a black matrix)

### DETAILED DESCRIPTION OF THE INVENTION

The colorant (A) in a colored photosensitive composition of the invention can be an organic colorant or an inorganic colorant. The organic colorant can be a pigment, a dye or a natural colorant. The inorganic colorant may be an inorganic pigment, such as metal oxides, metal complex salts and an inorganic salt of barium sulfate (Body pigment). Among the colorant, organic colorants, particularly organic pigments, are preferably used since they are excellent in heat resistance and coloring ability.

Examples of the organic pigements include compounds classified in pigments in Colour index (The Society of Dyers and Clolurists). Specific examples of the organic pigments include compounds of the following colour index (C.I.) number, although organic colorants usable in the present invention are not limited to the compouns:

C.I. Pigment yellow 1, C.I. Pigment yellow 3, C.I. Pigment yellow 12, C.I. Pigment yellow 13, C.I. Pigment yellow 14, C.I. Pigment yellow 15, C.I. Pigment yellow 16, C.I. Pigment yellow 17, C.I. Pigment yellow 20, C.I. Pigment yellow 24, C.I. Pigment yellow 31, C.I. Pigment yellow 53, C.I. Pigment yellow 83, C.I. Pigment yellow 86, C.I. Pigment yellow 93, C.I. Pigment yellow 94, C.I. Pigment yellow 109, C.I. Pigment yellow 110, C.I. Pigment yellow 117, C.I. Pigment yellow 125, C.I. Pigment yellow 128, C.I. Pigment yellow 137, C.I. Pigment yellow 138, C.I. Pigment yellow 139, C.I. Pigment yellow 147, C.I. Pigment yellow 148, C.I. Pigment yellow 150, C.I. Pigment yellow 153, C.I. Pigment yellow 154, C.I. Pigment yellow 166 and C.I. Pigment yellow 173;

C.I. Pigment orange 13, C.I. Pigment orange 31, C.I. Pigment orange 36, C.I. Pigment orange 38, C.I. Pigment orange 40, C.I. Pigment orange 42, C.I. Pigment orange 43, C.I. Pigment orange 51, C.I. Pigment orange 55, C.I. Pigment orange 59, C.I. Pigment orange 61, C.I. Pigment orange 64, C.I. Pigment orange 65, C.I. Pigment orange 71 and C.I. Pigment orange 73; C.I. Pigment red 9, C.I. Pigment red 97, C.I. Pigment red 105, C.I. Pigment red 122, C.I. Pigment red 123, C.I. Pigment red 144, C.I. Pigment red 149, C.I. Pigment red 166, C.I. Pigment red 168, C.I. Pigment red 176, C.I. Pigment red 177, C.I. Pigment red 180, C.I. Pigment red 192, C.I. Pigment red 209, C.I. Pigment red 215, C.I. Pigment red 216, C.I. Pigment red 224, C.I. Pigment red 242, C.I. Pigment red 254, C.I. Pigment red 264 and C.I. Pigment red 265

C.I. Pigment blue 15, C.I. Pigment blue 15:3, 15:4, C.I. Pigment blue 15:6 and C.I. Pigment blue 60;

C.I. Pigment violet 1, C.I. Pigment violet 19, C.I. Pigment violet 23, C.I. Pigment violet 29, C.I. Pigment violet 32, C.I. Pigment violet 36 and C.I. Pigment violet 38; C.I. Pigment green 7 and C.I. Pigment green 36; C.I. Pigment brown 23 and C.I. Pigment brown 23 25; and C.I. Pigment black 1 and C.I. Pigment black 7.

These organic pigments can be used singly or as a mixture of two or more of them.

The organic pigment can be, if necessary, subjected to a rosin treatment, a surface treatment using a pigment derivative having an acidic group or a basic group, or the like, a graft treatment on the pigment surface with a polymer, a fine particle treatment such as a sulfuric acid fine particle method, a washing for removing impurities with an organic solvent, water or the like.

Colorant (A) is used in an amount of usually 5-60% by mass, preferably 10-50% by mass base on the total solid contents of the colored photosensitive composition. The amount of 20% by mass or more, particularly 30% by mass or more is more preferable. Amount of organic pigment is preferably 50% by mass or more, more preferably 55% by mass or more, base or total amount of the colorant (A).

The binder polymer (B) is a polymer containing monomer units having oxetane structure. Examples of the monomer having oxetane structure include compounds having the oxetane structure represented by formula (I-1):

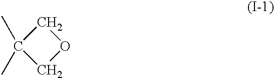

and a carbon to carbon double bond represented by formula (I-2)

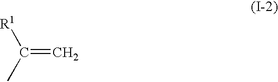

wherein R¹ represents a hydrogen atom or a methyl group. More specifically, examples of the compound include monomers represented by formula (I)

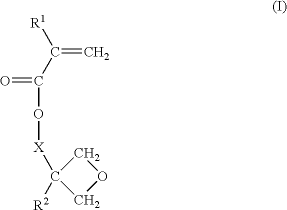

wherein R¹ is as defined above and X represents a methylene or ethylene group and R² represents a methyl or ethyl group.

Examples of the monomer include

3-methyl-3-methacryloxymethyl oxetane,

3-methyl-3-acryloxymethyl oxetane,

3-ethyl-3-methacryloxymethyl oxetane,

3-ethyl-3-acryloxymethyl oxetane,

3-methyl-3-methacryloxymethyl oxetane,

3-methyl-3-methacryloxyethyl oxetane,

3-methyl-3-acryloxyethyl oxetane, 3-ethyl-3-methacryloxy ethyl oxetane and 3-ethyl-3-acryloxyethyl oxetane.

The monomer unit with oxetane structure in the binder polymer is derived from monomers having oxetane structure, such as those exemplified above. The monomer unit with oxetane structure can be one single kind or combination of two or more kinds.

The binder polymer (B) is preferably a copolymer of a monomer having oxetane structure and other monomer(s) which can be co-polymerized with the monomer having oxetane structure. Examples of the other monomer include unsaturated carboxylic acids with at least one carboxyl group such as unsaturated monocarboxylic acid or unsaturated dicarboxylic acid. More specifically, acrylic acid, methacrylic acid, crotonic acid, itaconic acid, maleic acid and fumaric acid are exemplified. These monomers with carboxyl group(s) are compounds having carbon to carbon unsaturated double bond and can be used alone or in combination of two or more.

In addition to the above-mentioned unsaturated carboxylic acids, examples of the other monomer further include aromatic vinyl compounds such as styrene, α-methylstyrene, vinyltoluene and the like, unsaturated carboxylates such as methyl (meth)acrylate, ethyl (meth)acrylate, butyl (meth)acrylate, 2-hydroxylethyl (meth)acrylate, benzyl (meth)acrylate and the like, unsaturated aminoalkyl carboxylates such as aminoethyl acrylate and the like, unsaturated glycidyl carboxylates such as glycidyl (meth)acrylate and the like, vinyl carboxylates such as vinyl acetate and vinyl propionate and the like, vinyl cyanide compounds such as (meth)acrylonitrile and α-chloroacrylonitrile, and the like. These monomers can be co-polymerized with the monomer having oxetane structure and the above-mentioned unsaturated carboxylic acid, and can also be used each alone or in combination of two or more.

Examples of such copolymer include

3-ethyl-3-methacryloxymethyloxetane/benzyl methacrylate/methacrylic acid copolymer,

3-ethyl-3-methacryloxymethyloxetane/benzyl methacrylate/methacrylic acid/styrene copolymer,

3-ethyl-3-methacryloxymethyloxetane/methyl methacrylate/methacrylic acid copolymer,

3-ethyl-3-methacryloxymethyloxetane/methyl methacrylate/methacrylic acid/styrene copolymer and the like.

Content of the monomer unit in the copolymer derived from a monomer having oxetane group is preferably 3 to 95% by mass, more preferably from 5 to 90% by mass based on the total of monomer units. Content of the monomer unit in the copolymer derived from unsaturated carboxylic acids is preferably 5 to 50% by mass, more preferably from 10 to 40% by mass based on the total of monomers.

The binder polymer (B) preferably have weight-average molecular weight measured by gel permeation chromatography converted to polystyrene of from 5000 to 400000, more preferably from 10000 to 300000.

The binder polymer (B) is used in an amount of usually from 5 to 90% by weight, preferably from 20 to 70% by weight based on the total amount of all solid components in the colored photosensitive composition.

The photo-polymerizable compound (C) is a compound that can be polymerized by the action of an active radicals or an acid generated from the photo-polymerization initiator (D) by irradiation of light beam. In general, the photo-polymerizable compound (C) has a polymerizable carbon-carbon unsaturated bond. It can be a bi-functional, or other poly-functional monomer as well as a mono-functional monomer.

Examples of the mono-functional monomer include nonylphenylcarbitol acrylate, 2-hydroxy-3-phenoxypropyl acrylate, 2-ethylhexylcarbitol acrylate, 2-hydroxyethyl acrylate, N-vinylpyrrolidone and the like.

Examples of the bi-functional monomer include 1,6-hexanediol di(meth)acrylate, ethylene glycol di(meth)acrylate, neopentyl glycol di(meth)acrylate, triethylene glycol di(meth)acrylate, bis(acryloyloxyethyl) ether of bisphenol A, 3-methylpentanediol di(meth)acrylate and the like. Examples of the other poly-functional monomer include trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate and the like.

These photopolymerizable monomers can be used each alone or in combination of two or more. It is preferred that at least one bi-unctional or other poly-functional monomer is used. Amount of the photopolymerizable compound (C) is generally from 0.1 to 70 parts by mass, preferably from 1 to 60 parts by mass based on 100 parts by mass of the total amount of the binder polymer (B) and the photopolymerizable compound (C).

As the photo-polymerization initiator (D), active radical generators that generate an active radical by irradiation of light beam and acid generators that generate an acid by irradiation of light beam can be mentioned. Examples of the active radical generators include acetophenone-based polymerization initiators, benzoin-based polymerization initiators, benzophenone-based polymerization initiators, thioxanetone-based polymerization initiators, triazine-based polymerization initiators and other initiators.

Specific examples of the acetophenone-based polymerization initiator include oligomers of diethoxyacetophenone,

2-hydroxy-2-methyl-1-phenylpropane-1-one, benzyldimethylketal,

2-hydroxy-2-methyl-1-[4-(2-hydroxyethoxy)phenyl]propane-1-one, 1-hydroxycyclohexylphenylketone,

2-methyl-2-morpholino-1-(4-methylthiophenyl)propane-1-one,

2-benzyl-2-dimethylamino-1-(4-morpholinophenyl)butane-1-one and

2-hydroxy-2-methyl-1-[4-(1-methylvinyl)phenyl]propane-1-one, and the like.

Specific examples of the benzoin-based polymerization initiators include benzoin, benzoin methyl ether, benzoin ethyl ether, benzoin isopropyl ether, benzoin isobutyl ether and the like.

Specific examples of the benzophenone-based polymerization initiator include benzophenone, methyl o-benzoylbenzoate, 4-phenylbenzophenone, 4-benzoyl-4′-methyldiphenylsulfide, 3,3′,4,4′-tetra(tert-butylperoxycarbonyl)benzophenone, 2,4,6-trimethylbenzophenone and the like.

Specific examples of the thioxanetone-based polymerization initiator include 2-isopropylthioxanetone, 4-isopropylthioxanetone, 2,4-diethylthioxanetone, 2,4-dichlorothioxanetone, 1-chloro-4-propoxythioxanetone and the like.

Specific examples of the triazine-based polymerization initiator include

2,4-bis(trichloromethyl)-6-(4-methoxyphenyl)-1,3,5-triazine

2,4-bis(trichloromethyl)-6-(4-methoxynaphthyl)-1,3,5-triazine,

2,4-bis(trichloromethyl)-6-piperonyl-1,3,5-triazine,

2,4-bis(trichloromethyl)-6-(4-methoxystyryl)-1,3,5-triazine,

2,4-bis(trichloromethyl)-6-[2-(5-methylfuran-2-yl)ethenyl]-1,3,5-triazine,

2,4-bis(trichloromethyl)-6-[2-(furan-2-yl)ethenyl]-1,3,5-triazine,

2,4-bis(trichloromethyl)-6-[2-(4-diethylamino-2-methylphenyl)ethenyl]-1,3,5-triazine,

2,4-bis(trichloromethyl)-6-[2-(3,4-dimethoxyphenyl)ethenyl]-1,3,5-triazine and the like.

As the active radical generator,

2,4,6-trimethylbenzoyldiphenylphosphine oxide,

2,2′-bis(o-chlorophenyl)-4,4′,5,5′-tetraphenyl-1,2′-biimidazole, 10-butyl-2-chloroacridone, 2-ethylanthraquinone, benzil, 9,10-phenanethrenequinone, camphorquinone, methyl phenylglyoxylate, titanocene compounds and the like can be exemplified.

Commercially available active radical generators can also be used. Examples thereof include “Irgacure-907” (an acetophenone-based polymerization initiator, manufactured by CIBA-GEIGY), and the like.

Examples of acid generators include onium salts such as 4-hydroxyphenyldimethylsulfonium p-toluenesulfonate, 4-hydroxyphenyldimethylsulfonium hexafluoroantimonate, 4-acetoxyphenyldimethylsulfonium p-toluenesulfonate, 4-acetoxyphenylmethylbenzylsulfonium hexafluoroantimonate, triphenylsulfonium p-toluenesulfonate, triphenylsulfoniumhexafluoroantimonate, diphenyliodonium p-toluenesulfonate and diphenyliodonium hexafluoroantimonate; nitrobenzyltosylates, benzointosylates, and others.

Some of active radical generators are also acid generators. For example, the triazine-based polymerization initiators mentioned above can act as acid generators as well as active radical generators.

These photopolymerization initiators can be used each alone or in combination of two or more.

The colored photosensitive composition of the invention may further comprise a photopolymerization aid. The photopolymerization aid is used, in combination with the photo-polymerization initiator (D), for accelerating the polymerization of the photo-polymerizable compound (C) initiated by the photo-polymerization initiator (D). As the photopolymerization aid, for example, amine-based polymerization aids and alkoxyanthracene-based polymerization aids, and the like are exemplified.

Examples of amine-based polymerization aids include triethanolamine, methyldiethanolamine, triisopropanolamine, methyl 4-dimethylaminobenzoate, ethyl 4-dimethylaminobenzoate, isoamyl 4-dimethylaminobenzoate, 2-dimethylaminoethyl benzoate, 2-ethylhexyl 4-dimethylaminobenzoate, N,N-dimethylparatoluidine, 4,4′-bis(dimethylamino)benzophenone (commonly called Michler's ketone), 4,4′-bis(diethylamino)benzophenone, 4,4′-bis(ethylmethylamino)benzophenone and the like.

Examples of alkoxyanthracene-based polymerization aids include 9,10-dimethoxyanthracene, 2-ethyl-9,10-dimethoxyanthracene, 9,10-diethoxyanthracene, 2-ethyl-9,10-diethoxyanthracene and the like.

Commercially available photopolymerization aids can also be used. Examples thereof include “EBA-F” (manufactured by Hodogaya Chemical Co., Ltd.), and the like.

Amount of the photopolymerization aid is 10 mols or less, preferably from 0.01 to 5 mols or less based on 1 mol of the photo-polymerization initiator (D).

Total amount of the photo-polymerization initiator (D) and the photopolymerization aid is generally from 3 to 30 parts by mass, preferably from 5 to 25 parts by mass based on 100 parts by mass of the total amount of the binder polymer (B) and the photopolymerizable compound (C).

The photopolymerization aids can also be used each alone or in combination of two or more.

The colored photosensitive composition of the invention may be diluted with a solvent (E). Solvents that have been used for conventional colored photosensitive composition can be used in the invention.

Examples of the solvents include ethylene glycol monoalkyl ethers such as ethylene glycol monomethyl ether, ethylene glycol monoethyl ether, ethylene glycol monopropyl ether and ethylene glycol monobutyl ether; diethylene glycol dialkyl ethers such as diethylene glycol dimethyl ether, diethylene glycol diethyl ether, diethylene glycol dipropyl ether and diethylene glycol dibutyl ether;

ethylene glycol alkyl ether acetates such as methylcellosolve acetate and ethylcellosolve acetate; alkylene glycol alkyl ether acetates such as propylene glycol monomethyl ether acetate, propylene glycol monoethyl ether acetate, propylene glycol monopropyl ether acetate, methoxybutyl acetate and methoxypentyl acetate;

aromatic hydrocarbons such as benzene, toluene and xylene; ketones such as methyl ethyl ketone, acetone, methyl amyl ketone, methyl isobutyl ketone and cyclohexanone; alcohols such as ethanol, propanol, butanol, hexanol, cyclohexanol, ethylene glycol and glycerine;

esters such as ethyl 3-ethoxypropionate and methyl 3-methoxypropionate; cyclic esters such as γ-butyrolactone; and the like.

These solvents can be used each alone or in combination of two or more. The amount of the solvent used is preferably from 50 to 90% by weight, more preferably from 60 to 85% by mass based on the amount of the whole colored photosensitive composition including the solvent.

The colored photosensitive composition of the invention may further comprise an additive (F), if necessary. Examples of the additives include fillers, polymer compounds other than the binder polymer (B), surfactants, adherence promoters, antioxidants, ultraviolet absorbers, coagulation preventing agents, organic acids, organic amino compounds, hardeners and the like.

Specific examples of the fillers include glass, silica, alumina and the like.

Specific examples of the polymer compounds other than the binder polymer (B) include polyvinyl alcohol, polyacrylic acid, polyethylene glycol monoalkyl ether, polyfluoroalkyl acrylate and the like.

Specific examples of the surfactants include nonionic, cationic and anionic surfactants.

Specific examples of the adherence promoters include

vinyltrimethoxysilane, vinyltriethoxysilane,

vinyltris(2-methoxyethoxy)silane,

N-(2-aminoethyl)-3-aminopropylmethyldimethoxysilane,

N-(2-aminoethyl)-3-aminopropyltrimethoxysilane,

3-aminopropyltriethoxysilane,

3-glycidoxypropyltrimethoxysilane,

3-glycidoxypropylmethyldimethoxysilane,

2-(3,4-epoxycyclohexy)ethyltrimethoxysilane,

3-chloropropylmethyldimethoxysilane,

3-chloropropyltrimethoxysilane,

3-methacryloxypropyltrimethoxysilane,

3-mercaptopropyltrimethoxysilane and the like.

Specific examples of the antioxidants include

2,2-thiobis(4-methyl-6-t-butylphenol),

2,6-di-t-butylphenol and the like.

Specific examples of the ultraviolet absorbers include 2-(3-t-butyl-5-methyl-2-hydroxyphenyl)-5-chlorobenzotriazole, alkoxybenzophenone and the like.

Specific examples of the coagulation preventing agents include sodium polyacrylate.

Examples of the organic acid include aliphatic monocarboxylic acids such as formic acid, acetic acid, propionic acid, butyric acid, valeric acid, pivalic acid, caproic acid, diethylacetic acid, enanthylic acid, caprylic acid and the like;

aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, cyclohexanedicarboxylic acid, itaconic acid, citraconic acid, maleic acid, fumaric acid, mesaconic acid and the like; aliphatic tricarboxylic acids such as tricarballylic acid, aconitic acid, camphoronic acid and the like;

aromatic monocarboxylic acids such as benzoic acid, toluic acid, cumenic acid, hemellitic acid, mesitylenic acid and the like;

aromatic dicarboxylic acids such as phthalic acid, isophthalic acid, terephthalic acid and the like;

aromatic polycarboxylic acids such as trimellitic acid, trimesic acid, mellophanic acid, pyromellitic acid and the like; and others.

Examples of organic amino compounds include mono(cyclo)alkylamines such as n-propylamine, i-propylamine, n-butylamine, i-butylamine, sec-butylamine, t-butylamine, n-pentylamine, n-hexylamine, n-heptylamine, n-octylamine, n-nonylamine, n-decylamine, n-undecylamine, n-dodecylamine, cyclohexylamine, 2-methylcyclohexylamine, 3-methylcyclohexylamine, 4-methylcyclohexylamine and the like;

di(cyclo)alkylamines such as methylethylamine, diethylamine, methyl-n-propylamine, ethyl-n-propylamine, di-n-propylamine, di-i-propylamine, di-n-butylamine, di-i-butylamine, di-sec-butylamine, di-t-butylamine, di-n-pentylamine, di-n-hexylamine, methylcyclohexylamine, ethylcyclohexylamine, dicyclohexylamine and the like;

tri(cyclo)alkylamines such as dimethylethylamine, methyldiethylamine, triethylamine, dimethyl-n-propylamine, diethyl-n-propylamine, methyldi-n-propylamine, ethyldi-n-propylamine, tri-n-propylamine, tri-i-propylamine, tri-n-butylamine, tri-i-butylamine, tri-sec-butylamine, tri-t-butylamine, tri-n-pentylamine, tri-n-hexyalmine, dimethylcyclohexylamine, diethylcyclohexylamine, methyldicyclohexylamine, ethyldicyclohexylamine, tricyclohexylamine and the like;

mono(cyclo)alkanolamines such as 2-aminoethanol, 3-amino-1-propanol, 1-amino-2-propanol, 4-amino-1-butanol, 5-amino-1-pentanol, 6-amino-1-hexanol, 4-amino-1-cyclohexanol and the like;

di(cyclo)alkanolamines such as diethanolamine, di-n-propanolamine, di-i-propanolamine, di-n-butanolamine, di-i-butanolamine, di-n-pentanolamine, di-n-hexanolamine, di-(4-cyclohexanol)amine and the like;

tri(cyclo)alkanolamines such as triethanolamine, tri-n-propanolamine, tri-i-propanolamine, tri-n-butanolamine, tri-i-butanolamine, tri-n-pentanolamine, tri-n-hexanolamine, tri-(4-cyclohexanol)amine and the like;

amino(cyclo)alkanediols such as 3-amino-1,2-propanediol, 2-amino-1,3-propanediol, 4-amino-1,2-butanediol, 4-amino-1,3-butanediol, 4-amino-1,2-cyclohexanediol, 4-amino-1,3-cyclohexanediol, 3-dimethylamino-1,2-propanediol, 3-diethylamino-1,2-propanediol, 2-dimethylamino-1,3-propanediol, 2-diethylamino-1,3-propanediol and the like;

amino-group containing cycloalkanemethanols such as 1-aminocyclopentanonemethanol, 4-aminocyclopentanonemethanol, 1-aminocyclohexanonemethanol, 4-aminocyclohexanonemethanol, 4-dimethylaminocyclopentanemethanol, 4-diethylaminocyclopentanemethanol, 4-dimethylaminocyclohexanemethanol, 4-diethylaminocyclohexanemethanol and the like;

aminocarboxylic acids such as β-alanine, 2-aminobutyric acid, 3-aminobutyric acid, 4-aminobutyric acid, 2-aminoisobutyric acid, 3-aminoisobutyric acid, 2-aminovaleric acid, 5-aminovaleric acid, 6-aminocaproic acid, 1-aminocyclopropanecarboxylic acid, 1-aminocyclohexanecarboxylic acid, 4-aminocyclohexanecarboxylic acid and the like;

aromatic amines such as aniline, o-methylaniline, m-methylaniline, p-methylaniline, p-ethylaniline, p-n-propylaniline, p-i-propylaniline, p-n-butylaniline, p-t-butylaniline, 1-naphthylamine, 2-naphthylamine, N,N-dimethylaniline, N,N-diethylaniline, p-methyl-N,N-dimethylaniline and the like;

aminobenzylalcohols such as o-aminobenzylalcohol, m-aminobenzylalcohol, p-aminobenzylalcohol, p-dimethylaminobenzylalcohol, p-diethylaminobenzylalcohol and the like;

aminophenols such as o-aminophenol, m-aminophenol, p-aminophenol, p-dimethylaminophenol, p-diethylaminophenol and the like;

aminobenzoic acids such as m-aminobenzoic acid, p-aminobenzoic acid, p-dimethylaminobenzoic acid, p-diethylaminobenzoic acid and the like; and others.

Hardeners are used in order to increase the mechanical strength of the color pixel by hardening it through heat treatment after development. Examples of such hardeners include compounds which can cross-link a binder polymer by a reaction with the oxetane structure or the carboxyl group in the binder polymer under heating, and they harden the color pattern by the cross-linkage of the binder. The hardeners may also be compounds which can polymerize themselves by heating, and they harden the color pattern by self-polymerization. Examples of these compounds include epoxy compounds, oxetane compounds and the like.

Examples of the epoxy compounds include epoxy resins such as bisphenol A type epoxy resins, hydrogenated bisphenol A type epoxy resins, bisphenol F type epoxy resins, hydrogenated bisphenol F type epoxy resins, novolak type epoxy resins, other aromatic epoxy resins, alicyclic epoxy resins, heterocyclic epoxy resins, glycidyl ester resins, glycidyl amine resins, epoxidized oil and the like; brominated derivatives of these epoxy resins; aliphatic, alicyclic or aromatic epoxy compounds other than the epoxy resins and their brominated derivatives; epoxidized products of butadiene (co)polymers; epoxidized products of isoprene (co)polymers; glycidyl (meth)acrylate (co)polymers; triglycidyl isocyanurate and the like.

Examples of the oxetane compounds include carbonate bisoxetane, xylylene bisoxetane, adipate bisoxetane, terephtharate bisoxetane, cyclohexane dicarboxylic acid bisoxetane and the like.

The colored photosensitive composition of the invention may contain, together with a hardener, a compound which can cause the ring-opening polymerization of an epoxy group in epoxy compounds or an oxetane nucleus in oxetane compounds. Examples of such compounds include polybasic carboxylic acids, polybasic carboxylic acid anhydrides, acid generators and the like.

Examples of the polybasic carboxylic acids include aromatic polybasic carboxylic acids such as phthalic acid, 3,4-dimethylphthalic acid, isophthalic acid, terephthalic acid, pyromellitic acid, trimellitic acid, 1,4,5,8-naphthalenetetracarboxylic acid, 3,3′,4,4′-benzophenonetetracarboxylic acid and the like;

aliphatic polybasic carboxylic acids such as succinic acid, glutaric acid, adipic acid, 1,2,3,4-butanetetracarboxylic acid, maleic acid, fumaric acid, itaconic acid and the like;

alicyclic polybasic carboxylic acids such as hexahydrophthalic acid, 3,4-dimethyltetrahydrophthalic acid, hexahydroisophthalic acid, hexahydroterephthalic acid, 1,2,4-cyclopentanetricarboxylic acid, 1,2,4-cyclohexanetricarboxylic acid, cyclopentanetetracarboxylic acid, 1,2,4,5-cyclohexanetetracarboxylic acid and the like; and others.

Examples of polybasic carboxylic acid anhydrides include aromatic polybasic carboxylic acid anhydrides such as phthalic acid anhydride, pyromellitic acid anhydride, trimellitic acid anhydride, 3,3′,4,4′-benzophenonetetracarboxylic acid dianhydride and the like;

aliphatic polybasic carboxylic acid anhydrides such as itaconic acid anhydride, succinic acid anhydride, citraconic acid anhydride, dodecenylsuccinic acid anhydride, tricarballylic acid anhydride, maleic acid anhydride, 1,2,3,4-butanetetracarboxylic acid dianhydride and the like;

alicyclic polybasic carboxylic acid anhydrides such as hexahydrophthalic acid anhydride, 3,4-dimethyltetrahydrophthalic acid anhydride, 1,2,4-cyclopentanetricarboxylic acid anhydride, 1,2,4-cyclohexanetricarboxylic acid anhydride, cyclopentanetetracarboxylic acid dianhydride, 1,2,4,5-cyclohexanetetracarboxylic acid dianhydride, 1,2,3,6-tetrahydro-3,6-methanophthalic anhydride, nadic anhydride and the like;

ester-group containing carboxylic acid anhydrides such as ethylene glycol bistrimellitic acid anhydride, glycerol tristrimellitic acid anhydride and the like; and others.

Commercially available products for epoxy resin hardener may be used as the carboxylic acid anhydrides. Examples of such epoxy resin hardener include “Adeka Hardener EH-700” (trade name, available from Asahi Denka Kogyo K.K.), “Rikacid HH” (trade name, available from New Japan Chemicals Co., Ltd.), “MH-700” (trade name, available from New Japan Chemicals Co., Ltd.) and the like.

These hardeners can be used independently or in combination of two or more.

The colored photosensitive composition of the invention can be produced by mixing a colorant (A), a binder polymer (B), a photo-polymerizable compound (C) and a photo-polymerization initiator (D) in a solvent (E). When it contains an additive (F), the composition can be produced by mixing a colorant (A), a binder polymer (B), a photo-polymerizable compound (C), a photo-polymerization initiator (D) and an additive (F) in a solvent (E).

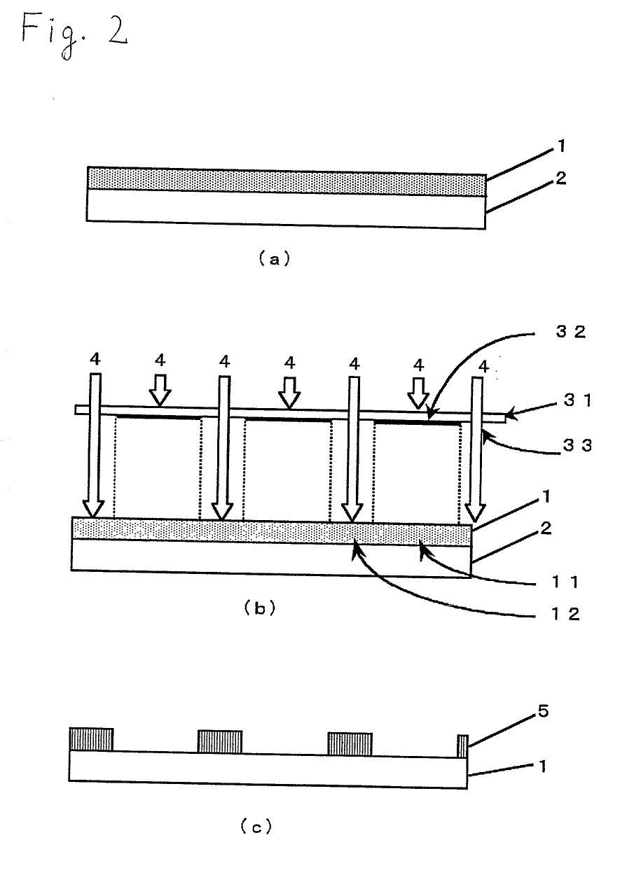

For making a color pattern (5) with the colored photosensitive composition of the invention, for example, a layer (1) of a colored photosensitive composition of the invention is formed on a substrate (2) (see FIG. 2(a)), said layer (1) is exposed to light by irradiating a light beam (4) through a photo-mask (3) (see FIG. 2(b)) and then the development is conducted.

Examples of the substrate (2) include glass plates, silicon wafers, plastic plates and the like. When a silicon wafer or the like is used as the substrate, charge-coupled devices (CCD) or the like may be formed on the surface of said silicon wafer or the like.

For forming the colored photosensitive composition layer (1) on the substrate (2), for example, the colored photosensitive composition diluted with a solvent is applied on the substrate by rotary coating method (spin-coat method), and then the solvent is evaporated.

Then, the substrate is exposed to light by irradiating a light beam (4). Usually, ultraviolet rays such as g-ray (wavelength: 436 nm), i-ray (wavelength: 365 nm) and the like are used as the light beam (4).

The light beam is irradiated through a photo-mask (3). The photo-mask herein is, for example, a glass plate (31) having, on its surface, a light-insulating layer (32) for shielding the light beam. The light beam (4) is shielded by the light-insulating layer (32). An area of the glass plate (31) having no light-insulating layer is the translucent area (33) that allows permeation of the light beam. The colored photosensitive composition layer (2) is exposed to a light according to a pattern of the translucent area (33). The intensity of the light beam to be irradiated is appropriately selected depending on kind and amount of the binder polymer (A), color and amount of the pigment (B), kind and amount of the photo-polymerizable compound (C), kind and amount of the photo-polymerization initiator (D) and others.

The development is carried out after the exposure to light. For the development, for example, the exposed colored photosensitive composition layer is immersed in a solution of a developer. Examples of the solution of a developer include aqueous solutions of an alkaline compound such as sodium carbonate, sodium hydroxide, potassium hydroxide, potassium carbonate, tetramethylammonium hydroxide and the like.

By development, a non-irradiated area (11), which is an area of the colored photosensitive composition layer having not irradiated with the light beam, is removed, while an irradiated area (12), which is an area having irradiated with the light beam, is remained and constitutes a color pattern (5).

Usually, by washing the product with water and drying after development, the desired color pattern (5) can be obtained.

Heat treatment may be applied after drying. By this heat treatment, the formed color pattern is hardened resulting in increase in the mechanical strength. Use of a colored photosensitive composition containing a hardener is preferred because the mechanical strength of the color pattern is improved further by the heat treatment. The temperature for heat treatment is usually 180° C. or above and preferably about 200° C. or above and 250° C. or under.

The color pattern (5) obtained in this manner, which was produced from the colored photosensitive composition of the present invention by irradiation of light beam, has excellent solvent resistance.

For obtaining a color filter by forming a color pixel of another color or a black matrix, the above procedure is repeated changing the color of the colorant (A). In this manner, color pattern of respective colors can be formed.

Using the colored photosensitive composition of the invention, color pattern having excellent solvent resistance can be formed even when the colored photosensitive composition contains the colorant (A) in a high concentration.

The invention will now be described in more detail with reference to Examples, which should not be construed as a limitation upon the scope of the invention.

### EXAMPLE 1

(Preparation of Binder Polymer A1)

Into a four-necked flask of 500 cm³ of inner volume equipped with a stirrer, a cooler and a thermometer 25.8 g of methacrylic acid, 105.7 g of benzylmethacrylate, 18.4 g of 3-ethyl-3-methacryloxymethyl oxetane, 278.5g of propyleneglycol monomethyletheracetate and 3.6 g of azo-bis-iso-butyronitrile were charged. The temperature of reaction mixture was kept from 65 to 75° C. for 5 hours under stirring to obtain binder polymer A1. The resulted polymer Al was a copolymer of methacrylic acid and benzylmethacrylate and 3-ethyl-3-methacryloxymethyl oxetane and polymerized in the charged amount ratio.

(Preparation of Colored Photo-Sensitive Resist Composition)

The components were mixed in the ratio shown in Table 1 and a colored photo-sensitive resist composition was obtained.

(Formation of Cyanine Blue Pixels)

On the surface of a glass substrate [manufactured by Corning Glass Corporation, Type 7059] (2) the above prepared colored photo-sensitive resist composition was spin-coated and dried for 3 minutes at 100° C. to form a layer of the colored photo-sensitive resist composition (1). After cooling i-line of wavelength 365 nm was irradiated to the colored photosensitive composition layer (1) through a photo-mask (3). A super-high pressure mercury lamp was used as a light source of the i-line with irradiated light amount of 150 mJ/cm².

Then the irradiated layer (1) was developed by immersing into a developer consisting of 0.05% by mass ratio of potassium hydroxide and 0.2% by mass ratio of sodium butylnaphthalene sulfonate and washed by pure water. After heating for 20 minutes at 230° C., a cyanine blue pixels (5) was formed. The resulted blue pixels were formed according to the desired pattern.

TABLE 1

| | | |
|---|---|---|
| Pigment | C.I. pigment blue 15:6 | 4.75 parts |
| | | by mass |
| Binder | | 5.00 parts |
| polymer A1 | | by mass |
| Photo-poly- | Dipentaerythritol hexaacylate | 5.86 parts |
| merizable | (“KAYARAD DPHA” | by mass |
| compound | Nihon Kayaku Kogyou K.K.) | |
| Photo-conden- | “Irgacure-907” | 1.30 parts |
| sation | (CIBA-GEYGY) | by mass |
| initiator | “KAYACURE DETX-S” | 0.65 parts |
| | (Nihon Kayaku Kougyou K.K) | by mass |
| Additive | Pigment dispersing agent | 1.44 parts |
| | | by mass |
| Solvent | Propyleneglycol | 81 parts by |
| | monomethyletheracetate | mass |

Evaluation

1. Solvent Resistance

A colored photo-sensitive resist layer (1) was formed according to the same manner as above except for that i-ray was irradiated without using a photo-mask, in a manner that the colored resist layer (1) covered whole surface of the glass substrate (2).

To the surface of resulting cured colored resist layer 2 cm³ of N-methyl-2 pyrrolidone (NMP) was added dropwise. After leaving for 30 minutes at 40° C., the surface of the cured color resist layer was washed by 2 cm³ of NMP. No coloring of the washing liquid was observed by visual inspection.

After washing by NMP the cured color resist layer was washed by pure water, and dried. Then, the surface of the layer was observed by a reflecting optical microscope. The surface of the layer was smooth.

2. Peeling Test

According to the method specified by JIS K5400, the cured dry layer of colored photo-sensitive resist was cross-cut to provide 100 square specimens of 1 mm×1 mm size. The peeling test is carried out to the specimens using a tape made of cellophane. No peeling-off of the resist layers from glass substrate (2) was observed.

### Comparative Example 1

(Preparation of Binder Polymer A2)

The same process was applied for preparation of binder polymer A2 as Example 1 except that amount of benzyl methacrylate was changed to 124.1 g and 3 -ethyl-3-methacryloxymethyloxetane was not used. The binder polymer A2 was a copolymer of methacrylic acid and benzyl methacrylate and copolyerized according to the ratio of charged amount.

(Preparation of Colored Photo-Sensitive Resist Composition and Formation of Cyanine Blue Pixels)

Another colored photo-sensitive resist composition was prepared according to the same process as in Example 1 except that 5.0 parts by mass of binder polymer (A2) was used instead of using binder polymer (A1)

(Evaluation)

By the same process as in Example 1 except for using the above described colored photosensitive composition instead of the photosensitive composition in Example 1, the colored and cured resist film was formed covering the whole surface of the glass substrate (2). The film was evaluated according to the same manner as in Example 1.

In the solvent resistant test coloring of washing liquid was observed by visual observation. A close observation of the surface of the colored resist layer by a reflecting optical microscope indicated presence of fine unevenness on the surface of the layer after subsequent washing of the surface by NMP water and drying.

No peeling-off of the colored layer from the glass substrate (2) was observed.

1. A colored photosensitive composition comprising a colorant (A), a binder polymer (B) containing monomer unit having oxetane structure, a photo-polymerizable compound (C) and a photo-polymerization initiator (D).

2. The colored photosensitive composition according to claim 1 wherein the binder polymer (B) is a copolymer of a monomer having oxetane structure and other monomer(s).

3. The colored photosensitive composition according to claim 2 wherein content of the monomer unit in the copolymer derived from the monomer having oxetane group is 3 to 95% by mass based on the total of monomer units.

4. The colored photosensitive composition according to claim 2 wherein the binder polymer (B) is used in an amount of from 5 to 90% by weight based on the total amount of all solid components in the colored photosensitive composition.

5. The colored photosensitive composition according to claim 1 wherein colorant (A) is used in an amount of usually 5-60% by mass base on the total solid contents of the colored photosensitive composition.

6. A method for making a color pattern (5) which comprises forming a layer (1) of a colored photosensitive composition on a substrate (2), exposing said layer (1) to a light beam (4) through a photo-mask, and developing the exposed layer (1).

7. A color pattern formed according to the method of claim 6.

8. A color filter comprising a color pattern according to claim 7.
